(19) United States
(12) Patent Application Publication
(10) Pub. No.: US 2026/0045764 A1
(43) Pub. Date: Feb. 12, 2026

(54) Method for Monitoring a Laser Control Process in a Laser System

(71) Applicant: Robert Bosch GmbH, Stuttgart (DE)

(72) Inventors: Joern Hoffarth, Reutlingen (DE); David Copeto, Ludwigsburg (DE); Stefan Noe, Stuttgart (DE)

(21) Appl. No.: 19/289,453

(22) Filed: Aug. 4, 2025

(30) Foreign Application Priority Data
Aug. 7, 2024 (DE) 10 2024 207 479.9

(51) Int. Cl. H01S 5/042

(52) U.S. Cl. CPC H01S 5/042

(57) ABSTRACT

A method for monitoring a laser control process in a laser system includes (i) performing the laser control process in the laser system using a first analog-digital converter, and (ii) monitoring the laser control process in the laser system using a second analog-digital converter. The second analog-digital converter is configured as a redundancy to the first analog-digital converter in the laser system. A computer program, an apparatus, and a storage medium for this purpose is also disclosed.

This application claims priority under 35 U.S.C. § 119 to application no. DE 10 2024 207 479.9, filed on Aug. 7, 2024 in Germany, the disclosure of which is incorporated herein by reference in its entirety.

The disclosure relates to a method for monitoring a laser control process in a laser system. The disclosure further relates to a computer program, an apparatus, and a storage medium for this purpose.

### BACKGROUND

Analog-to-digital converters (AD converters) play an essential role in controlling laser systems by converting analog signals into digital data required for precise regulation and control of the laser. These converters are critical to the detection and processing of signals that affect the performance, stability, and accuracy of the laser.

Laser systems are used in a variety of applications, such as for distance measurement. Reliable and accurate control of the laser is of great importance in these applications. The quality of the data supplied by the AD converters directly affects the control mechanisms of the laser, including power control.

A failure or fault in an AD converter can have serious consequences on the performance and safety of the laser system. For example, a defective AD converter may lead to incorrect control commands, which may result in an uncontrolled change in laser power or direction. This may not only compromise the quality of the work performed, but can also cause potentially hazardous situations, particularly in medical or industrial environments. Moreover, failures in signal processing by AD converters can lead to significant degradation in system reliability and efficiency, which can result in high costs for repairs and downtime.

Therefore, the development of robust and highly precise AD converters is central to ensuring the reliable and safe functioning of laser systems.

### SUMMARY

The subject of the disclosure is a method, a computer program, a device, a computer-readable storage medium, and a laser system having the features set forth below. Further features and details of the disclosure will emerge from the description and the drawings. Features and details which are described in connection with the method according to the disclosure naturally also apply in connection with the computer program according to the disclosure, the apparatus according to the disclosure, the computer-readable storage medium according to the disclosure as well as the laser system according to disclosure, and vice versa in each case, so that a reciprocal reference is always possible with regard to the disclosure of the disclosure.

The subject matter of the disclosure is in particular a method for monitoring a laser control process in a laser system, comprising the following steps, wherein the steps may be repeated and/or performed sequentially. In particular, the laser system is a laser rangefinder. The laser control process relates in particular to controlling laser power of a laser in the laser system. This may vary, for example, as a function of a diode current of a laser diode of the laser.

In a first step, preferably the laser control process of the laser system is performed using a first analog-digital converter. In particular, a laser in the laser system is controlled during the process, for example in terms of laser power. To carry out the laser control process of the laser in the laser system using the analog-digital converter, the following procedure can be applied: A laser current of the laser may be controlled by a control loop, in particular using a measurement controller. The analog-digital converter may convert the analog signal of the laser current into a digital signal that may be processed by a microcontroller. The microcontroller may compare the digital signal of the laser current to a reference signal and adjust the laser current accordingly to ensure a stable output power of the laser. The control loop may also be applied to other parameters of the laser system, such as temperature, to ensure optimal performance and stability of the laser.

In a further step, preferably the laser control process of the laser system is monitored using a second analog-digital converter, wherein the second analog-digital converter is configured as a redundancy to the first analog-digital converter in the laser system. Monitoring of the laser control process can occur, for example, based on a comparison of respective output values of the analog-digital converters. Monitoring may be performed, for example, based on analysis of data from a Serial Peripheral Interface (SPI) communication channel. Both analog-digital converters preferably have a corresponding interface for this purpose and communicate via the same SPI communication channel. Thus, it may be advantageously determined if the first analog-digital converter outputs erroneous output values, which may lead to erroneous actuation of a laser in the laser system. Due to the fact that only the monitoring check, but not the control, is carried out via the communication channel, the laser power is advantageously kept stable as well, in particular even in the event of an error in the communication channel.

The method according to the disclosure may advantageously redundantly monitor the laser system. A failure of the first analog-digital converter may advantageously be detected by the second analog-digital converter and, if necessary, be compensated. Accordingly, the method may further comprise the step of the second analog-digital converter assuming a function of the first analog-digital converter in the event of an error in the first analog-digital converter.

Optionally, it may be contemplated that the second analog-digital converter uses a different time base with respect to a sampling rate than the first analog-digital converter. For example, the second analog-digital converter could scan twice as often or even half as often as the first analog-digital converter. Thus, for example, the first analog-digital converter can scan the peak power of the laser, while the second analog-digital converter can record the average laser power. For example, the average laser power may be critical to comply with a regulatory standard. Scanning more quickly helps, for example, to control and/or ramp up the laser more quickly.

Advantageously, it may be contemplated in the context of the disclosure that the second analog-digital converter uses different filtering than the first analog-digital converter. The filtering could have other configuration parameters in the second analog-digital converter, for example a different filter bandwidth. It is also conceivable that low-pass filtering is provided in one analog-digital converter and band-pass filtering is provided in the other analog-digital converter.

It may optionally be possible for the second analog-digital converter to use a different measurement method than the first analog-digital converter. For example, the first analog-digital converter may be a sigma-delta converter and the second analog-digital converter may be a successive approximation register (SAR). In addition, it may be contemplated that the first and the second analog-digital converters are not connected to the same supply voltage, reference voltage and/or system clock. Due to the different design and system integration, faults may advantageously not affect both analog-digital converters simultaneously.

It may be contemplated in the context of the disclosure that monitoring the laser control process comprises monitoring a power supply of the first and second analog-digital converters. For example, an internal voltage reference source, to which both analog-digital converters are connected, can be scanned. In this way, it is possible that the integrity of the power supply is monitored for both analog-digital converters. Possible errors in the power supply can thereby be detected early and, if necessary, corrected by a microcontroller of the laser system, for example also by a switching it off.

The subject matter of the disclosure is also a laser system, in particular a laser rangefinder, comprising a laser, a measurement controller and an application-specific integrated circuit. In particular, the application-specific integrated circuit comprises first and second analog-digital converters. The first and second analog-digital converters are preferably arranged physically separated from each other and share the same power supply and the same quartz crystal as the clock. The laser system is in particular configured to perform the method according to the disclosure.

Another object of the disclosure is a computer program, in particular a computer program product, comprising commands which, when the computer program is executed by a computer, cause the computer to carry out the method according to the disclosure. The computer program according to the disclosure thus brings with it the same advantages as have been described in detail with reference to a method according to the disclosure.

The disclosure also relates to an apparatus for data processing which is configured so as to carry out the method according to the disclosure. The apparatus can be a computer, for example, that executes the computer program according to the disclosure. The computer can comprise at least one processor for executing the computer program. A non-volatile data memory can be provided as well, in which the computer program can be stored and from which the computer program can be read by the processor for execution.

The disclosure can also relate to a computer-readable storage medium, which comprises the computer program according to the disclosure and/or commands that, when executed by a computer, prompt said computer program to carry out the method according to the disclosure. The storage medium is configured as a data memory such as a hard drive and/or a non-volatile memory and/or a memory card, for example. The storage medium can, for example, be integrated into the computer.

In addition, the method according to the disclosure can also be designed as a computer-implemented method. Alternatively or additionally, at least one of the disclosed method steps may be computer-implemented and/or performed automatically.

### BRIEF DESCRIPTION OF THE DRAWINGS

Further advantages, features, and details of the disclosure emerge from the following description, in which exemplary embodiments of the disclosure are described in detail with reference to the drawings. The features mentioned in the claims and in the description can each be essential to the disclosure individually or in any combination. The figures show:

FIG. 1 a schematic visualization of a method, a device, a storage medium, and a computer program according to exemplary embodiments of the disclosure,

FIG. 2 a schematic illustration of a laser system according to exemplary embodiments of the disclosure.

### DETAILED DESCRIPTION

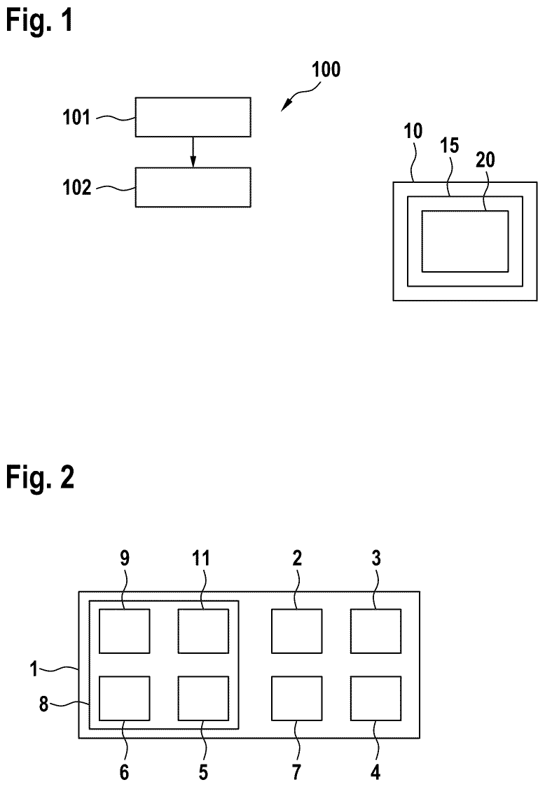

FIG. 1 schematically illustrates a method 100, a device 10, a storage medium 15, and a computer program 20 according to exemplary embodiments of the disclosure.

FIG. 1 shows in particular an exemplary embodiment of a method 100 for monitoring a laser control process in a laser system 1. In a first step 101, the laser control process of the laser system 1 is carried out using a first analog-digital converter 2. In a second step 102, the laser control process of the laser system 1 is monitored using a second analog-digital converter 3. The second analog-digital converter 3 is configured as a redundancy to the first analog-digital converter 2 in the laser system 1.

The method of the present disclosure relates to a laser system 1, and according to exemplary embodiments, in particular to a laser rangefinder that uses the indirect Time of Flight (iToF) measurement method. For this exemplary embodiment, reference is made to FIG. 2. For example, this laser rangefinder 1 operates by measuring a phase shift of a modulated light signal emitted by the laser rangefinder and reflected by a target object. The following is a description of how the Indirect Time of Flight (iToF) measurement works. First, a laser 3, in particular a laser diode of the laser 3, can transmit intensity-modulated light in the laser rangefinder 1, for example in the infrared or visible area, towards a target object. The modulation is in particular carried out with a sinusoidal or square wave. The intensity-modulated light subsequently strikes the target object and is reflected back to the laser rangefinder 1. A detector 4 in the measuring device can now receive the reflected light. Since the light takes a certain amount of time to travel the distance, there is a phase shift between the transmitted signal and the received signal. This phase shift between the transmitted signal and the received signal may then be measured. This phase shift is in particular proportional to the distance of the light traveled. The distance may then be calculated from the phase shift taking into account the wavelength of the modulation and the speed of light. It may further be provided that a reference phase is determined with a second detector having a constant distance (not shown) to determine the phase shift based on a comparison to the reference phase.

The laser rangefinder 1 may comprise a measurement controller 2. The measurement controller 2 in particular assumes control of the laser 3.

Thus, the measurement controller 2 may control an emission of the laser 3 by controlling switching the power on and off, as well as controlling intensity of a laser beam of the laser 3. This can ensure that the laser beam is transmitted at the correct power and with the correct characteristics.

Furthermore, a laser beam of the laser system 1 may be modulated, for example in the form of pulsed light and/or a continuous wave of variable modulation frequency. Upon receipt by the detector 4 of the reflected laser beam, the measurement controller 2 may process the received signal. This includes, for example, amplification, filtering and conversion of the received analog signal into a digital signal for further analysis, in particular by an analog-digital converter 5. Furthermore, the phase shift between the transmitted signal and the received signal may be measured and optionally compared to the reference phase. According to exemplary embodiments, the laser system 1 further preferably comprises a second analog-digital converter 6, which is redundantly connected to the first analog-digital converter 5.

The measurement controller 2 may also periodically perform calibrations to ensure that the measurements are precise. For this purpose, it can monitor a state of the laser 3 and the detector 4 to ensure that they are functioning properly.

In addition, the laser system 1, in particular the laser rangefinder, can comprise a first and second analog-digital converter 5, 6. The respective analog-digital converters 5 preferably convert analog signals received from the detector 4 into digital signals. In particular, these signals represent an intensity of light transmitted by the laser 3. The digital conversion may allow the phase shift between the transmitted signal and the received signal to be analyzed. The digital signals provided by the respective analog-digital converter 5 may be further filtered, amplified, and processed to reduce noise and improve signal quality.

The method according to exemplary embodiments advantageously eliminates a periphery of the analog-digital converters 5, 6 in a microcontroller 7 of the laser system 1 and a further electrical connection to the microcontroller 7.

By way of the physically separated second analog-digital converter 6 in the application-specific integrated circuit 8 (ASIC) of the laser system 1 and the independently running measurement controller 2, a standard SPI communication channel can be used to monitor the measurement controller 2. Both analog-digital converters 5, 6 share the same power supply 9 and quartz crystal 11 as the clock. Therefore, monitoring the power supply 9 and checking that the application-specific integrated circuit 8 is responsive is necessary. An internal voltage reference source may be scanned to monitor the power supply 9. In addition to switching off the laser system 1 via SPI, if the application-specific integrated circuit 8 is faulty, the microcontroller 7 may also stop current flow separately via a semiconductor switch.

The above explanation of the embodiments describes the present disclosure solely within the scope of examples. Of course, individual features of the embodiments can be freely combined with one another, if technically feasible, without leaving the scope of the present disclosure.

What is claimed is:

1. A method for monitoring a laser control process in a laser system, comprising:
performing the laser control process in the laser system using a first analog-digital converter; and
monitoring the laser control process in the laser system using a second analog-digital converter,
wherein the second analog-digital converter is configured as a redundancy to the first analog-digital converter in the laser system.

2. The method according to claim 1, wherein the second analog-digital converter is configured to use a different time base with respect to a sampling rate than the first analog-digital converter.

3. The method according to claim 1, wherein the second analog-digital converter is configured to use a different filtering than the first analog-digital converter.

4. The method according to claim 1, wherein the second analog-digital converter is configured to use a different measurement method than the first analog-digital converter.

5. The method according to claim 1, wherein the monitoring the laser control process comprises monitoring a power supply of the first and second analog-digital converters.

6. The method according to claim 1, wherein the monitoring is performed based on analysis of data from a Serial Peripheral Interface communication channel.

7. A computer program, comprising instructions that, when the computer program is executed by a computer, cause the computer to carry out the method according to claim 1.

8. A device for data processing, configured to carry out the method according to claim 1.

9. A computer-readable storage medium, comprising instructions which, when executed by a computer, cause said computer to carry out the steps of the method according to claim 1.

10. A laser system comprising a laser, a measurement controller, and an application-specific integrated circuit, wherein:
the application-specific integrated circuit comprises a first and a second analog-digital converter,
the first and the second analog-digital converters are arranged physically separated from each other and share the same power supply and the same quartz crystal as the clock, and
the laser system is configured to perform the method according to claim 1.
